(19) United States
(12) Patent Application Publication
(10) Pub. No.: US 2017/0133245 A1
(43) Pub. Date: May 11, 2017

(54) SUBSTRATE MOUNTING MECHANISM AND SUBSTRATE PROCESSING APPARATUS

(71) Applicant: TOKYO ELECTRON LIMITED, Tokyo (JP)

(72) Inventor: Hachishiro IIZUKA, Yamanashi (JP)

(21) Appl. No.: 15/347,719

(22) Filed: Nov. 9, 2016

(30) Foreign Application Priority Data
Nov. 11, 2015 (JP) 2015-221118

(51) Int. Cl. H01L 21/67; H01L 21/683

(52) U.S. Cl. CPC H01L 21/67103; H01L 21/67069; H01L 21/6833

(57) ABSTRACT

A substrate mounting mechanism, for heating and cooling a substrate mounted thereon, includes a heating member having a heating unit configured to heat a substrate mounted on the heating member, a cooling member configured to cool the substrate and provided below the heating member, and an attaching/detaching unit configured to separate the heating member from the the cooling member and allow the heating member to come into contact with the cooling member. The substrate mounted on the heating member is heated in a state where the heating member and the cooling member are separated from each other by the attaching/detaching unit and power is supplied to the heating unit. Further, the substrate mounted on the heating member is cooled in a state where the heating member is made to be in contact with the cooling member by the attaching/detaching unit and no power is supplied to the heating unit.

### CROSS-REFERENCE TO RELATED APPLICATIONS

This application claims priority to Japanese Patent Application No. 2015-221118 filed on Nov. 11, 2015, the entire contents of which is incorporated herein by reference.

### FIELD OF THE INVENTION

The disclosure relates to a substrate mounting mechanism capable of heating and cooling a substrate mounted thereon, and a substrate processing apparatus using the substrate mounting mechanism.

### BACKGROUND OF THE INVENTION

When a substrate such as a semiconductor wafer or the like is processed, a plurality of processes may be performed at different temperatures. For example, an etching process is performed at a low temperature and, then, an etching residue removing process is performed at a high temperature. In order to repeatedly perform such processes on a plurality of substrates, heating and cooling of the substrates need to be repeated. When such processes are performed on a single substrate mounting table, a long period of time is required for temperature control. Therefore, generally, substrate mounting tables set to different processing temperatures are provided in respective chambers (see, Japanese Patent Application Publication No. 2005-039185).

However, when there are two chambers and a substrate mounting table is provided in each of the two chambers, a footprint of an apparatus is increased and the cost is also increased. Further, a substrate transfer time is increased. Therefore, it is difficult to obtain a high throughput.

To that end, a technique capable of rapidly heating and cooling a substrate on a single mounting table is being studied. For example, Japanese Patent Application Publication No. 2015-056624 discloses a substrate temperature control unit including: a mounting table configured to mount thereon a substrate and having therein a temperature control medium path; a substrate elevation unit configured to support a substrate and vertically move the substrate between a first position on the mounting table and a second position above the mounting table; a cooling unit configured to supply a temperature control medium to the temperature control medium path to control a temperature of the substrate located at the first position to a first temperature as a cooling temperature; a heating unit having an LED array having LEDs for emitting light of a wavelength, which can be absorbed by the substrate, from the mounting table side and configured to control a temperature of the substrate located at the second position to a second temperature as a heating temperature by heating the substrate with the light; and a light-transmitting window provided at the mounting table and configured to transmit the light emitted from the heating unit. Accordingly, the heating unit and the cooling unit can respectively heat and cool the substrate without thermally affecting each other. As a result, the heating and the cooling can be performed within an extremely short period of time.

However, the substrate temperature control unit disclosed in Japanese Patent Application Publication No. 2015-056624 has a complicated structure because it is required to form the LED array and the light-transmitting window at the substrate mounting table and also required to cool the LEDs.

### SUMMARY OF THE INVENTION

In view of the above, the disclosure provides a substrate mounting mechanism capable of rapidly heating and cooling a substrate with a relatively simple structure, and a substrate processing apparatus using the substrate mounting mechanism.

In accordance with an aspect, there is provided a substrate mounting mechanism for heating and cooling a substrate mounted thereon, which includes: a plate-shaped heating member having a heating unit configured to heat a substrate mounted on the heating member; a cooling member configured to to cool the substrate and provided below the heating member, the heating member and the cooling member being attachable to and detachable from each other; and an attaching/detaching unit configured to separate the heating member from the cooling member and allow the heating member to come into contact with the cooling member, wherein the substrate mounted on the heating member is heated in a state where the heating member and the cooling member are separated from each other by the attaching/detaching unit and power is supplied to the heating unit, and the substrate mounted on the heating member is cooled in a state where the heating member is made to be in contact with the cooling member by the attaching/detaching unit and no power is supplied to the heating unit.

In accordance with another aspect, there is provided a substrate processing apparatus for performing on a substrate a first process at a first temperature as a cooling temperature and a second process at a second temperature as a heating temperature, the apparatus including: a chamber accommodating a substrate; and the above-described substrate mounting mechanism provided in the chamber, wherein the substrate is heated from the first temperature to the second temperature in a state where the heating member and the cooling member are separated from each other and power is supplied to the heating unit and the substrate is cooled from the second temperature to the first temperature in a state where the heating member and the cooling member are in contact with each other and no power is supplied to the heating unit.

### BRIEF DESCRIPTION OF THE DRAWINGS

The objects and features of the disclosure will become apparent from the following description of embodiments, given in conjunction with the accompanying drawings, in which:

FIG. 1 is a cross sectional view schematically showing a configuration of a substrate mounting mechanism according to an embodiment;

FIG. 2 is an enlarged cross sectional view showing a part of the substrate mounting mechanism shown in FIG. 1;

FIGS. 3A to 3C are schematic diagrams for explaining an operation of the substrate mounting mechanism; and

FIG. 4 is a cross sectional view showing an example of a substrate processing apparatus including the substrate mounting mechanism according to the embodiment.

### DETAILED DESCRIPTION OF THE EMBODIMENTS

Hereinafter, embodiments will be described in detail with reference to the accompanying drawings.

(Configuration of Substrate Mounting Mechanism)

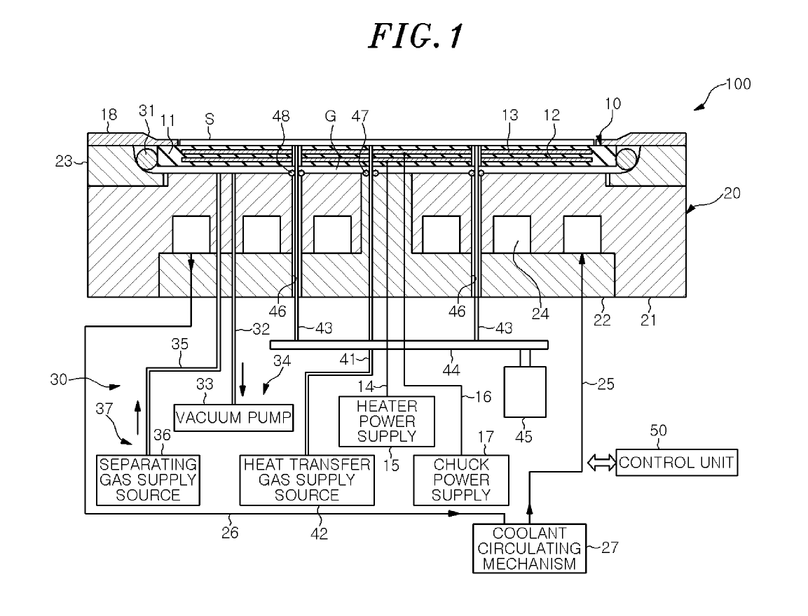

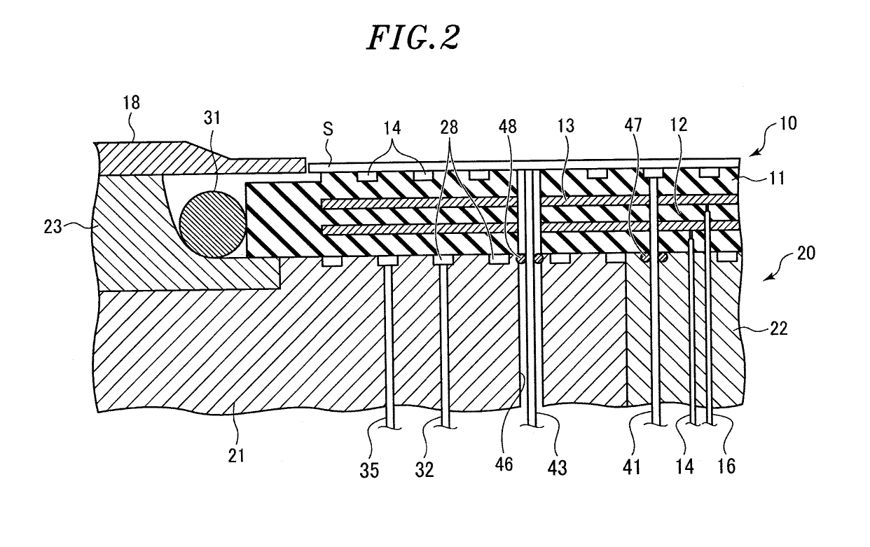

FIG. 1 is a cross sectional view schematically showing a configuration of a substrate mounting mechanism according to an embodiment. FIG. 2 is an enlarged cross sectional view showing a part of the substrate mounting mechanism shown in FIG. 1. FIG. 1 shows a state in which a heating member and a cooling member which will be described later are separated from each other. FIG. 2 shows a state in which the heating member and the cooling member are in contact with each other.

A substrate mounting mechanism 100 of the present embodiment mounts thereon a substrate in a chamber of a substrate processing apparatus for appropriately processing a substrate in a vacuum atmosphere and performs heating and cooling of the substrate mounted thereon. Specifically, the substrate mounting mechanism 100 is configured to change a temperature of a substrate S mounted thereon between a first temperature as a cooling temperature and a second temperature as a heating temperature.

The substrate processing apparatus including the substrate mounting mechanism 100 performs a first process at the first temperature as the cooling temperature and a second process at the second temperature as the heating temperature. The substrate processing is not particularly limited. For example, it is possible to perform etching as the first process at the first temperature as the cooling temperature and then perform residue removal as the second process at the second temperature as the heating temperature. On the other hand, it is also possible to heat a film formed on a substrate at the second temperature as the heating temperature and then rapidly cool the substrate to the first temperature as the cooling temperature. In addition, the substrate is not particularly limited, and there may be used various substrates such as a semiconductor substrate (semiconductor wafer), a flat panel display (FPD) substrate, a solar cell substrate and the like.

The substrate mounting mechanism 100 includes: a plate-shaped heating member 10 for heating a substrate S mounted thereon; a cooling member 20 for cooling the substrate S, which is provided below the heating member 10 and configured to be attachable to and detachable from the heating member 10; and an attaching/detaching unit 30 for vertically moving the heating member 10 to separate the heating member 10 from the cooling member 20 or make the heating member 10 contact with the cooling member 20.

The heating member 10 includes: a thin plate-shaped main body 11 made of an insulator such as alumina or the like; a heater 12, embedded in the main body 11, for heating the substrate S; and a sheet-shaped or mesh-shaped attracting electrode 13, embedded in the main body 11, having a size corresponding to that of the substrate S. The heater 12 is connected to a heater power supply 15 through a power feed line 14. The attracting electrode 13 is connected to a chuck power supply 17 through a power feed line 16. Therefore, the heating member 10 for heating the substrate S also serves as an electrostatic chuck for electrostatically attracting the substrate S. By supplying power to the heater 12, the heating member 10 is heated to a predetermined temperature. A thickness of the heating member 10 is preferably 1 mm to 6 mm, e.g., 2 mm. Due to a thin thickness of the heating member 10, the temperature can be rapidly increased.

As will be described later, the heating member 10 is vertically movable, so that pin contact using a spring may be used for the power feed portions of the power feed lines 14 and 16. Or, wire welding may be used instead of the pin contact. The power feed lines 14 and 16 extend to a position below the cooling member 20 through holes formed vertically in the cooling member 20.

The cooling member 20 includes: an upper plate 21 having therein a coolant path 24 and having a surface facing the heating member 10; a lower plate 22 provided below the upper plate 21 to cover the coolant path 24; and a ring-shaped member 23 provided around an outer periphery of a top surface of the upper plate 21. The upper plate 21 is made of a metal having high thermal conductivity, e.g., aluminum or copper. The lower plate 22 is made of a metal that has high thermal conductivity and is easily joined to the upper plate 21, e.g., aluminum, copper, nickel, or nickel alloy. The ring-shaped member 23 is made of, e.g., aluminum, nickel, or a nickel alloy. Or, the ring-shaped member 23 may be a ceramic member having high thermal conductivity.

The coolant path 24 is connected to a coolant supply line 25 and a coolant discharge line 26. The coolant supply line 25 and the coolant discharge line 26 are connected to a coolant circulating mechanism 27. Accordingly, a coolant is supplied from the coolant circulating mechanism 27 to the coolant path 24 to be circulated. The coolant may be, e.g., a fluorine-based liquid (trade mark: Fluorinert, Galden or the like) or water. By circulating the coolant in the coolant path 24, the cooling member 20 is cooled to a predetermined temperature. The entire thickness of the cooling member 20 is 10 mm to 50 mm. An outer diameter of the cooling member 20 is greater than that of the heating member 10. The cooling member 20 has a sufficiently large thermal capacity compared to that of the heating member 10. Therefore, the substrate S can be rapidly cooled by the cooling member 20 via the heating member 10.

A guide ring 18 is provided to cover the top surface of the ring-shaped member 23 and an outer peripheral portion of a substrate mounting portion of the top surface of the heating member 10 so that the top surface of the ring-shaped member 23 and the top surface of the heating member 10 separated from the cooling member 20 are substantially flush with each other. The guide ring 18 serves as a restricting unit for restricting a separation distance between the cooling member 20 and the heating member 10.

The attaching/detaching unit 30 includes: a seal ring 31 provided between the heating member 10 and the ring-shaped member 23 of the cooling member 20; a suction unit 34 for evacuating a space between the heating member 10 and the cooling member 20 by an operation of a vacuum pump 33, the suction unit 34 having a gas exhaust line 32 connected to the space between the heating member 10 and the cooling member 20 and the vacuum pump 33 connected to the gas exhaust line 32; and a separating gas supply unit 37 for supplying a separating gas from a separating gas supply source 36 to the space between the heating member 10 and the cooling member 20 through a separating gas line 35.

The seal ring 31 is made of an elastic material such as a synthetic rubber or the like. Due to its elasticity, the heating member 10 and the cooling member 20 are separated from each other and a gap G is formed therebetween. A cross sectional diameter of the seal ring 31, the arrangement of the seal ring 31 and the like are controlled such that the gap G becomes 0.2 mm to 2 mm, e.g., 0.4 mm. When the heating member 10 and the cooling member 20 are separated from each other, the heating member 10 and the cooling member 20 are thermally insulated from each other. In this state, by supplying power to the heater 12 of the heating member 10, it is possible to realize a heating mode in which the substrate S mounted on the heating member 10 is heated to the second temperature.

In order to switch the heating mode to a cooling mode, the space between the heating member 10 and the cooling member 20 is evacuated by the suction unit 34. Accordingly, the heating member 10 is moved toward the cooling member 20 and the seal ring 31 is deformed, which brings the heating member 10 into contact with the cooling member 20. By making the heating member 10 and the cooling member 20 come into contact with each other in a state where no power is supplied to the heater 12 of the heating member 10, the heating member 10 is cooled to the first temperature and the substrate S on the heating member 10 is rapidly cooled to the first temperature by the cooling member 20. Specifically, as shown in FIG. 2, the top surface of the cooling member 20 is embossed and a continuous recess 28 is formed on the top surface. The gas exhaust line 32 is connected to the recess 28. By exhausting the recess 28 through the gas exhaust line 32 by the vacuum pump 33, the space between the heating member 10 and the cooling member 20 is evacuated and the heating member 10 and the cooling member 20 are made to be in contact with each other. As a consequence, the cold heat from the cooling member 20 is transferred to the substrate S through the heating member 10, and the substrate S is rapidly cooled to the first temperature. Since the substrate mounting mechanism 100 of the present embodiment is used for vacuum processing, it is required to set a pressure in the recess 28 to be lower than a pressure in the chamber by the vacuum pump 33.

In order to switch the cooling mode to the heating mode, the operation of the suction unit 34 is stopped and a separating gas is supplied from the separating gas supply unit 37 to the space between the heating member 10 and the cooling member 20. Therefore, a pressure of the separating gas as well as the elastic force of the sealing member 31 is applied to the heating member 10. Accordingly, the heating member 10 is rapidly raised and separated from the cooling member 20. As a result, the heating member 10 and the cooling member 20 are thermally insulated from each other. Specifically, as shown in FIG. 2, the separating gas line 35 is connected to the recess 28 formed on the top surface of the cooling member 20. The pressure in the recess 28 is increased by the separating gas flowing through the separating gas line 35. Due to the pressure of the separating gas as well as the elastic force of the seal ring 31, the heating member 10 is rapidly raised and separated from the cooling member 20. Accordingly, the heating member 10 and the cooling member 20 are thermally insulated from each other, and the substrate S mounted on the heating member can be rapidly heated by the heating member 10. As for the separating gas, an inert gas such as N₂ gas, Ar gas or the like is used. The heating member 10 may be separated from the cooling member 20 only by using the elasticity of the seal ring 31 without using the separating gas. The separating gas may be used supportively. On the contrary, the heating member 10 may be separated from the cooling member 20 only by using the separating gas.

A heat transfer gas, e.g., He gas, is supplied from a heat transfer gas supply source 42 to the backside of the substrate S mounted and held on the heating member 10 through a heat transfer gas line 41. Specifically, as shown in FIG. 2, the top surface of the main body 11 of the heating member 10 is embossed and a continuous recess 14 is formed on the top surface. The heat transfer gas line 41 is connected to the recess 14, and the heat transfer gas is supplied to the backside of the substrate S. Thus, heat transfer between the substrate S and the heating member 10 is enhanced. Accordingly, the temperature of the substrate S can be controlled with high accuracy by the heating member 10. A joint portion between the heat transfer gas line 41 and the heating member 10 and the cooling member 20 is sealed by a seal ring 47.

The substrate mounting mechanism 100 includes an elevation unit for vertically moving the substrate S. The elevation unit includes: three (only two are shown in FIG. 1) elevating pins 43 for supporting and vertically moving the substrate S while penetrating through vertical holes 46 formed in the heating member 10 and the cooling member 20; a supporting plate 44 for supporting the three elevating pins 43; and a driving unit 45 for vertically moving the elevating pins 43 through the supporting plate 44. By retracting the elevating pins 43 inside the heating member 10 by the driving unit 45, the substrate S is mounted on the heating member 10. By projecting the elevating pins 43 by the driving unit 45, the substrate S reaches a transfer position above the heating member 10. By locating the elevating pins 43 to the transfer position, the substrate S is delivered between a transfer unit (not shown) and the elevating pins 43. Joint portions between the elevating pins 43 and the heating member 10 and the cooling member 20 in the holes 46 are sealed by respective seal rings 48. The number of the elevating pins 43 is not limited to three and may vary depending on the size of the substrate S.

The substrate mounting mechanism 100 further includes a control unit 50 for controlling the respective components, e.g., the heater power supply 15, the chuck power supply 17, the coolant circulating mechanism 27, the vacuum pump 33, the separating gas supply source 36, the heat transfer gas supply source 42, the driving unit and the like.

(Operation of Substrate Mounting Mechanism)

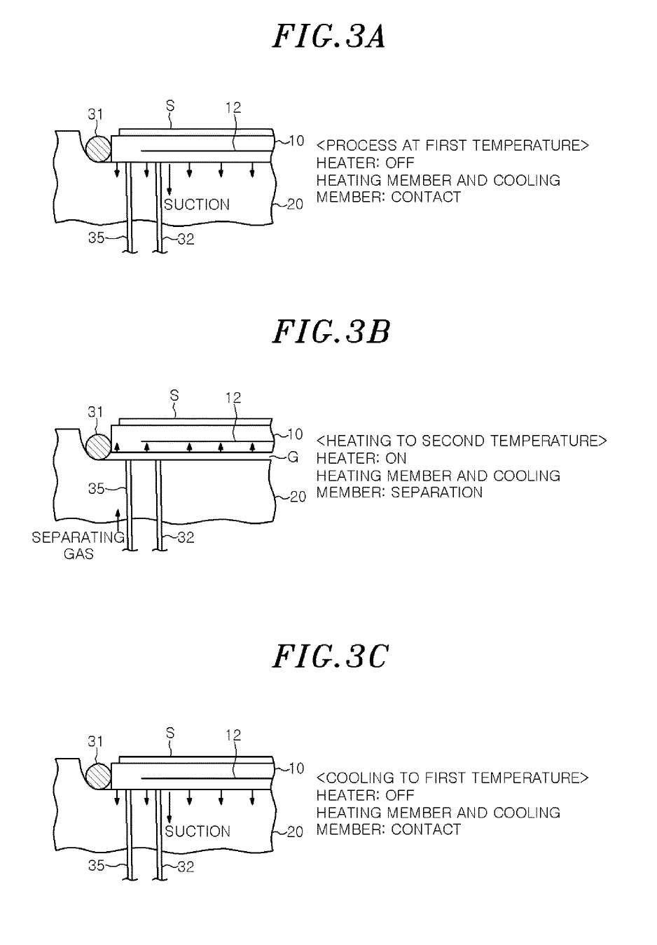

Hereinafter, an operation of the substrate mounting mechanism configured as described above will be described with reference to the schematic diagrams of FIGS. 3A to 3C.

In the case of performing a first process on the substrate S at the first temperature as the cooling temperature (e.g., 15° C. to 30° C.) in the processing chamber of the substrate processing apparatus, the heating member 10 and the cooling member 20 are separated and thermally insulated from each other in the initial state due to the elasticity of the seal ring 31, so that the space between the heating member 10 and the cooling member 20 is evacuated by the vacuum pump 33 of the suction unit 34 and the heating member 10 is moved toward the cooling member 20 to make contact therewith as shown in FIG. 3A. At this time, the heater 12 of the heating member 10 is switched to an off state. If the substrate S is mounted on the mounting surface of the heating member 10 in that state, the heat from the cooling member 20 having therein the coolant path 24 through which a cooling medium flows is transferred to the substrate S through the heating member 10 and the substrate S is controlled to the first temperature as the cooling temperature.

In order to heat the substrate S from the first temperature as the cooling temperature to the second temperature as the heating temperature (e.g., 80° C. to 180° C.), the operation of the suction unit 34 is stopped and the separating gas is supplied to the space between the heating member 10 and the cooling member 20 by the separating gas supply unit 37 as shown in FIG. 3B. Accordingly, the pressure of the separating gas as well as the elastic force of the seal ring 31 is applied to the heating member 10, and the heating member 10 is rapidly raised and separated from the cooling member 20. As a consequence, the heating member 10 and the cooling member 20 are thermally insulated from each other. If power is supplied to the heater 12 of the heating member 10 in that state, the substrate S mounted on the heating member 10 is rapidly heated by the heating member 10. The heating member 10 and the cooling member 20 may be separated from each other only by using the elastic force of the seal ring 31 without using the separating gas. The separating gas may be used supportively only when the elastic force is not sufficient to separate the heating member 10 and the cooling member 20. Alternatively, the heating member 10 and the cooling member 20 may be separated from each other only by using the separating gas.

In order to cool the substrate S heated as described above, in a state where no power is supplied to the heater 12 of the heating member 10, the heating member 10 is made to be in contact with the cooling member by evacuating the space between the heating member 10 and the cooling member 20 by the suction unit 34 as shown in FIG. 3C. At this time, the heating member 10 has small thermal capacity due to its thin thickness, whereas the cooling member 20 has sufficiently large thermal capacity compared to that of the heating member 10. Therefore, the heating member 10 is rapidly cooled by the cold heat of the cooling member 20, and the substrate on the heating member 10 is rapidly cooled to the first temperature.

Since the substrate can be rapidly heated and cooled, the temperature can be changed within a short period of time in the case of repeatedly performing on a single substrate or a plurality of substrates the first process at the first temperature as the cooling temperature and the second process at the second temperature as the heating temperature. Accordingly, a throughput can be improved.

As described above, in the present embodiment, the substrate mounting mechanism includes the plate-shaped heating member 10 configured to heat the substrate S mounted thereon, the cooling member 20 provided below the heating member 10 to cool the substrate S and configured to be attachable to and detachable from the heating member 10, and the attaching/detaching unit 30 configured to vertically move the heating member 10 to separate the heating member 10 from the cooling member 20 or to make the heating member 10 contact with the cooling member 20. The heating of the substrate S is performed in a state where the heating member 10 and the cooling member 20 are separated from each other and power is supplied to the heater 12, and the cooling of the substrate S is performed in a state where the heating member 10 and the cooling member 20 are in contact with each other and no power is supplied to the heater 12. Accordingly, the heating and the cooling can be rapidly performed by a simple structure.

Actually, by using a substrate mounting mechanism including the heating member 10 having a thickness of 2 mm and having the configuration shown in FIG. 1 and changing the temperature between the first temperature as the cooling temperature set to 40° C. and the second temperature as the heating temperature set to 100° C., it was possible to perform the temperature change within a short period of time of 20 sec to 40 sec.

The moving distance of the heating member, when separating the heating member 10 from the cooling member 20 and making the heating member 10 contact with the cooling member 20, may be 0.2 mm to 2 mm, e.g., 0.4 mm. Therefore, there may be used a simple means in which the vacuum pump is used for the contact and the elastic force of the seal ring and/or the separating gas is used for the separation. Since it is unnecessary to use a mechanical means, generation of particles can be reduced.

### Example of Substrate Processing Apparatus Including Substrate Mounting Mechanism According to Embodiment

Hereinafter, an example of the substrate processing apparatus including the substrate mounting mechanism according to the embodiment will be described.

In this example, there will be described a substrate processing apparatus for performing non-plasma etching on the substrate S at the first temperature as the cooling temperature and then removing residue on the substrate S by heating the substrate S to the second temperature.

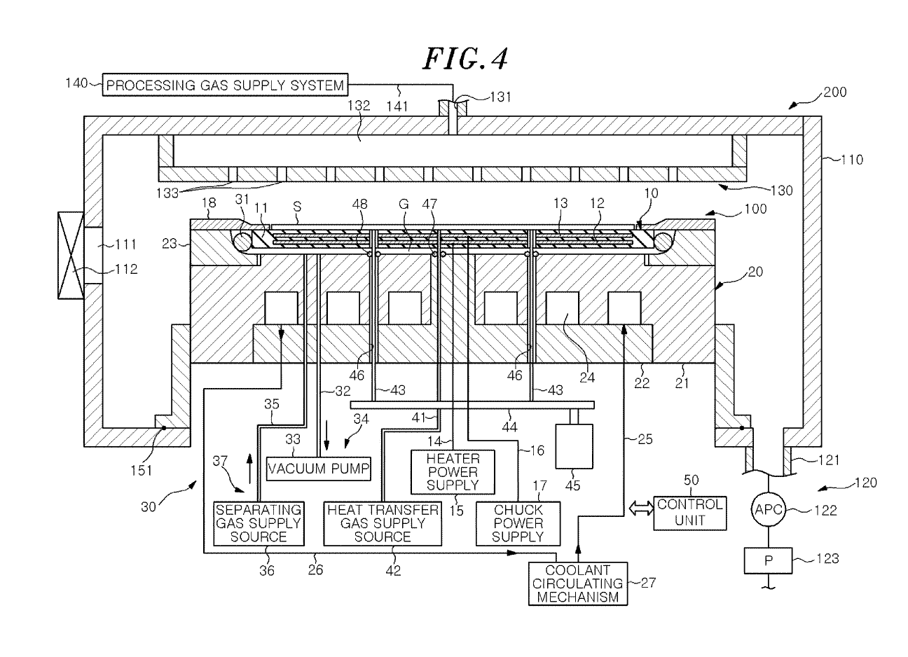

FIG. 4 is a cross sectional view showing an example of the substrate processing apparatus including the substrate mounting mechanism according to the embodiment. The substrate processing apparatus 200 in this example includes an evacuable chamber 110 and the substrate mounting mechanism 100 having the above-described configuration. The substrate mounting mechanism 100 is provided at a bottom portion of the chamber 110. The substrate processing apparatus 200 further includes a gas exhaust unit 120 provided at the bottom portion of the chamber 110, a shower head 130 provided at an upper portion of the chamber 110, and a processing gas supply system 140 for supplying a processing gas to the shower head 130. A loading/unloading port 111 for loading/unloading the substrate S is formed in a sidewall of the chamber 110. The loading/unloading port 111 is opened/closed by a gate valve 112. The substrate mounting mechanism 100 is attached to the bottom portion of the chamber 110 by a supporting member 150. A seal ring 151 is provided between the supporting member 150 and the bottom portion of the chamber 110.

The gas exhaust unit 120 has a gas exhaust line 121 connected to the bottom portion of the chamber 110, an automatic pressure control (APC) valve 122 provided in the gas exhaust line 121, and a vacuum pump 123 for evacuating the chamber 110 through the gas exhaust line 121.

The shower head 130 is attached to a ceiling portion of the chamber 110. A gas inlet port 131 is provided at an upper portion of the shower head 130. A gas diffusion space 132 is formed in the shower head 130. A plurality of gas injection holes 133 is formed at a bottom surface of the shower head 130.

The processing gas supply system 140 is configured to supply an etching gas used for performing non-plasma etching on a predetermined film on the substrate S and an inert gas used for removing the residue by heat and purging the chamber 110 into the shower head 130 from the gas inlet port 131 through the line 141. As for the etching gas, it is possible to use, e.g., HF gas, F₂ gas, NH₃ gas or the like. As for the inert gas, it is possible to use N₂ gas or Ar gas.

In the substrate processing apparatus 200 configured as described above, the gate valve 112 is opened and the substrate S is loaded into the chamber 110 through the loading/unloading port 111 by a transfer unit (not shown). The substrate S is transferred onto the elevating pins 41 in a projected state and then mounted on the heating member 10 of the substrate mounting mechanism 100 by lowering the elevating pins 43. Next, a pressure in the chamber 110 is controlled to a predetermined vacuum level by the gas exhaust unit 120. Thereafter, the substrate S is electrostatically attracted onto the heating member 10 by applying a predetermined voltage to the attracting electrode 13.

In that state, as described above, in the substrate mounting mechanism 100, no power is supplied to the heater 12 of the heating member 10 and the heating member 10 is made to be in contact with the cooling member 20 by evacuating the space between the heating member 10 and the cooling member 20 by the suction unit 34. Accordingly, the substrate S is controlled to the first temperature as the cooling temperature, e.g., 15° C. to 30° C., by the cooling member 20 of which temperature is controlled by circulating the coolant.

In that state, an etching gas is supplied from the processing gas supply system 140 to the shower head 130 and then is introduced into the chamber 110 through the shower head 130. As a consequence, a predetermined film is formed on the substrate S.

Upon completion of the etching, the inert gas is introduced into the chamber 110 through the shower head 130 and, then, the inert gas is introduced into the chamber 110 so that the inside of the chamber 110 is set to an inert gas atmosphere. As described above, in the substrate mounting mechanism 100, the operation of the suction unit 34 is stopped and the separating gas is supplied to the space between the heating member 10 and the cooling member 20 by the separating gas supply unit 37. Therefore, the pressure of the separating gas as well as the elastic force of the seal ring 31 is applied to the heating member 10. Accordingly, the heating member 10 is rapidly raised and separated from the cooling member 20. As a consequence, the heating member 10 and the cooling member 20 are thermally insulated from each other. If power is supplied to the heater 12 of the heating member 10 in that state, the substrate S mounted on the heating member 10 is rapidly heated to the second temperature, e.g., 80° C. to 180° C., by the heating member 10. By heating the substrate S to the second temperature, the residue remaining after the etching is removed.

After the residue is removed, no power is supplied to the heater 12 of the heating member 10 and the heating member 10 is made to be in contact with the cooling member 20 by evacuating the space between the heating member 10 and the cooling member 20 by the suction unit 34. Accordingly, the substrate S can be rapidly cooled to the first temperature. Upon completion of the cooling, the gate valve 112 is opened and the cooled substrate is unloaded from the loading/unloading port 111 by the transfer unit (not shown).

In the substrate processing apparatus 200, the substrate S is heated and cooled by the substrate mounting mechanism 100, so that the switching between the temperature for the non-plasma etching and the temperature for the residue removal can be carried out within an extremely short period of time. Therefore, it is possible to remarkably improve the throughput of the processing in the case of repeatedly performing the cooling (etching) and the heating (residue removal) on a single substrate and even in the case of repeatedly performing the heating and the cooling on a plurality of substrates.

(Other Applications)

The disclosure is not limited to the above-described embodiment and may be variously modified within the scope of the disclosure. For example, in the disclosure, the cooling temperature is a relative temperature with respect to the heating temperature and is not limited to a temperature lower than an ambient temperature. In the above-described embodiment, the first temperature as the cooling temperature is set to 15° C. to 30° C. and the second temperature as the heating temperature is set to and 80° C. to 180° C. However, the first temperature and the second temperature are not limited thereto and may vary.

In the above-described embodiment, the substrate processing apparatus performs the etching at the first temperature as the cooling temperature and then performs the residue removal or ashing at the second temperature as the heating temperature. However, as long as the heating and the cooling of the substrate are performed, the substrate processing apparatus may perform the processing at the heating temperature and then perform the processing at the cooling temperature without being limited to the above-described embodiment.

In the above-described embodiment, the substrate mounting mechanism is used for performing vacuum processing. However, the substrate mounting mechanism is not limited thereto and may also be used for performing processing under an atmospheric atmosphere. For example, in a substrate inspection apparatus such as a wafer prober or the like, the substrate mounting mechanism may be used for performing inspection by repeating the heating and the cooling of the substrate. In that case, convection of air occurs between the heating member and the cooling member separated from each other and this may lead to deterioration of the temperature controllability. Therefore, it is preferable to remove the air flowing between the heating member and the cooling member by injecting air as a separating gas. In the case of performing processing under an atmospheric atmosphere, the substrate may be held by the heating member serving as a vacuum chuck or a mechanical chuck instead of the electrostatic chuck.

While the disclosure has been shown and described with respect to the embodiments, it will be understood by those skilled in the art that various changes and modifications may be made without departing from the scope of the disclosure as defined in the following claims.

What is claimed is:

1. A substrate mounting mechanism for heating and cooling a substrate mounted thereon, comprising:
a plate-shaped heating member having a heating unit configured to heat a substrate mounted on the heating member;
a cooling member configured to cool the substrate and provided below the heating member, the heating member and the cooling member being attachable to and detachable from each other; and
an attaching/detaching unit configured to separate the heating member from the cooling member and allow the heating member to come into contact with the cooling member,
wherein the substrate mounted on the heating member is heated in a state where the heating member and the cooling member are separated from each other by the attaching/detaching unit and power is supplied to the heating unit, and
the substrate mounted on the heating member is cooled in a state where the heating member is made to be in contact with the cooling member by the attaching/detaching unit and no power is supplied to the heating unit.

2. The substrate mounting mechanism of claim 1, wherein the substrate is mounted on the heating member in a chamber held in a vacuum state.

3. The substrate mounting mechanism of claim 2, wherein the heating member includes:
a main body made of an insulator;
a heater provided in the main body, the heater serving as the heating unit; and
an attracting electrode provided in the main body,
wherein the heating member serves as an electrostatic chuck configured to electrostatically attract the substrate by applying a voltage to the attracting electrode.

4. The substrate mounting mechanism of claim 3, wherein pin contact using a spring or wire welding is used for power feed portions of the heater and the attracting electrode.

5. The substrate mounting mechanism of claim 1, wherein the heating member has a thickness of 1 mm to 6 mm.

6. The substrate mounting mechanism of claim 1, wherein the cooling member has a coolant path and is cooled to a predetermined temperature by circulating a coolant in the coolant path.

7. The substrate mounting mechanism of claim 1, wherein the attaching/detaching unit includes a suction unit for making the heating member contact with the cooling member by evacuating a space between the heating member and the cooling member.

8. The substrate mounting mechanism of claim 1, wherein the attaching/detaching unit includes an elastic member provided between the heating member and the cooling member and configured to separate the heating member and the cooling member from each other and/or a separating gas supply unit configured to supply a separating gas to the space between the heating member and the cooling member.

9. The substrate mounting mechanism of claim 1, wherein the attaching/detaching unit sets a gap between the heating member and the cooling member separated from each other to 0.2 mm to 2 mm.

10. A substrate processing apparatus for performing on a substrate a first process at a first temperature as a cooling temperature and a second process at a second temperature as a heating temperature, the apparatus comprising:
a chamber configured to accommodate a substrate; and
the substrate mounting mechanism, which is described in claim 1, provided in the chamber,
wherein the substrate is heated from the first temperature to the second temperature in a state where the heating member and the cooling member are separated from each other and power is supplied to the heating unit and the substrate is cooled from the second temperature to the first temperature in a state where the heating member and the cooling member are in contact with each other and no power is supplied to the heating unit.

11. The substrate processing apparatus of claim 10, further comprising:
a processing gas supply system configured to supply a processing gas to the chamber; and
a gas exhaust unit configured to exhaust the chamber.
